(19) United States
(12) Patent Application Publication
(10) Pub. No.: US 2014/0084956 A1
(43) Pub. Date: Mar. 27, 2014

(54) PROBE HEAD TEST FIXTURE AND METHOD OF USING THE SAME

(71) Applicant: Dennis Glenn L. Surell, Markham (CA)

(72) Inventor: Dennis Glenn L. Surell, Markham (CA)

(21) Appl. No.: 13/624,575

(22) Filed: Sep. 21, 2012

(51) Int. Cl. G01R 35/00; H05K 3/30; G01R 31/00

(52) U.S. Cl. 324/756.05; 29/832

(57) ABSTRACT

Various probe testing load board structures and methods of using the same are disclosed. In one aspect, a method of testing a load board of a probe testing system is provided. The method includes electrically engaging a shorting substrate with conductor structures of the load board. The shorting substrate is operable to establish one or more electrical pathways between the tester and at least one electronic component of the load board. An electrical test is performed on the at least one electronic component using the one or more electrical pathways.

### BACKGROUND OF THE INVENTION

1. Field of the Invention

This invention relates generally to semiconductor processing, and more particularly to systems and methods of testing aspects of a probe testing system.

2. Description of the Related Art

Current integrated circuits routinely include many tens or even hundreds of millions of transistors and other circuit devices configured in arrangements of staggering complexity. Not surprisingly, testing of integrated circuits is vital to ensure that both the huge numbers of circuit devices and the myriad of manufacturing steps required to make those devices meet or exceed design specifications. One type of electrical test routinely performed on integrated circuits is performed at the wafer level and involves establishing ohmic contact with certain areas of an integrated circuit using a special instrument known as a probe system. After ohmic contact is established, the tester of the probe system electrically stimulates the integrated circuit in a variety of ways to test various functionalities thereof. Another type of testing for chips destined for packages is performed after the individual chips are diced from the wafer and mounted into packages.

A conventional probe testing system consists of a load board, a probe head mounted on the load board and a tester. The probe head includes a collection of conductor pins or needles that project away from the load board and are used to establish the ohmic contact with areas on a semiconductor die of a wafer, often referred to as a device under test (DUT). The load board include plural surface contacts or POGO pads, which are selectively contacted by POGO pins, also housed by the tester, in order to establish electrical pathways to the DUT. A typical load board includes many components, such as relays, that are used to test various aspects of the DUT. These relays can often have very high switching speeds. Improper operation or failure of the relays can lead to potential false failure readings for otherwise good die. A given load board is usually tailored to test a particular DUT. If a new DUT, or stepping thereof, is produced, a new load board is normally required to debug the new DUT.

While a probe testing system, and its attendant load board, is useful to debug a DUT, a technical problem exists as to how to debug the load board. As just noted, failure or poor performance of a load board relay can yield false readings for a DUT. One conventional method of testing a load board involves the use of a multi-meter. This method can be very laborious, particularly if the load board includes complex circuitry and input/output (I/O) layouts. Furthermore, the multi-meter method does not provide for high-speed testing. Another conventional method requires so-called “flying probe testers” or a probe card analyzer. These variants are standalone machines that tend to be expensive and dedicated to usage in the load board or probe card manufacturer's site.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of testing a load board of a probe testing system is provided. The method includes electrically engaging a shorting substrate with conductor structures of the load board. The shorting substrate is operable to establish one or more electrical pathways between the tester and at least one electronic component of the load board. An electrical test is performed on the at least one electronic component using the one or more electrical pathways.

In accordance with another aspect of an embodiment of the present invention, a method of manufacturing is provided that includes fabricating a shorting substrate and plural conductor structures on the shorting substrate. The plural conductor structures are operable to establish ohmic contact with conductor structures of a load board of a probe testing system that includes a tester. The shorting substrate is operable to establish one or more electrical pathways between the tester and at least one electronic component of the load board.

In accordance with another aspect of an embodiment of the present invention, an apparatus is provided that includes a fixture engagable with a load board of a probe testing system. The probe testing system has a tester and a load board. The load board has at least one electronic component. The fixture includes a shorting substrate that is operable to establish one or more electrical pathways between the tester and the least one electronic component.

In accordance with another aspect of an embodiment of the present invention, an apparatus is provided that includes a load board that has at least one electronic component and is operable to transmit electrical signals to and from a tester. A shorting substrate is coupled to the load board and operable to establish one or more electrical pathways between the tester and the least one electronic component.

### BRIEF DESCRIPTION OF THE DRAWINGS

The foregoing and other advantages of the invention will become apparent upon reading the following detailed description and upon reference to the drawings in which:

FIG. 1 is a combined pictorial and schematic view of a conventional probe testing system;

FIG. 2 is a pictorial view of an exemplary embodiment of a probe tester fitted with an exemplary fixture to enable debugging of a load board;

FIG. 3 is a sectional view of a portion of the probe testing system depicted in FIG. 2;

FIG. 4 is a portion of FIG. 3 shown at greater magnification;

FIG. 5 is a schematic view of a portion of an exemplary probe testing system; and

FIG. 6 is a flow chart illustrating an exemplary testing method.

### DETAILED DESCRIPTION OF SPECIFIC EMBODIMENTS

A probe testing system is disclosed that includes a load board and a tester. The tester is ordinarily designed to make selective contact with the load board and run scripts to diagnose circuitry of a DUT in contact with a probe head of the load board. In addition, a fixture is mounted to the load board in lieu of a probe head. The fixture includes a shorting substrate that establishes electrical pathways to components of the load board, such as relays. In this way, the load board can be quickly debugged. Additional details will now be described.

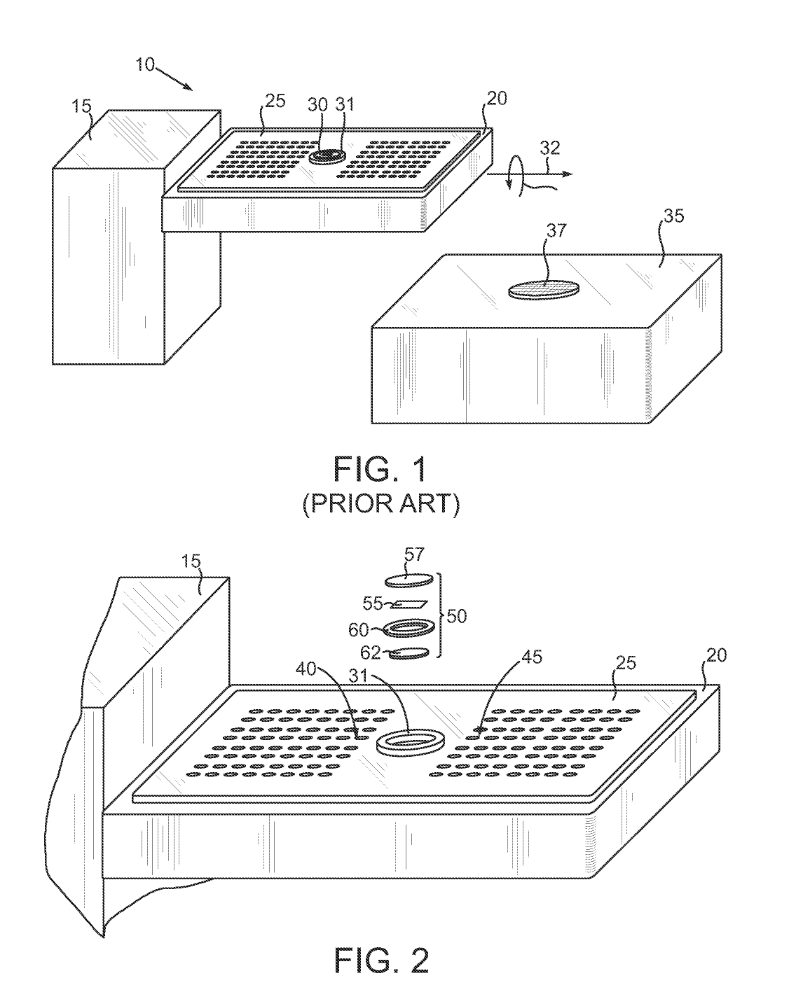

In the drawings described below, reference numerals are generally repeated where identical elements appear in more than one figure. Turning now to the drawings, and in particular to FIG. 1, therein is shown a combined pictorial and schematic view of an exemplary conventional probe testing system 10 (hereinafter probe system 10) that includes a tester 15 with a pivotable support deck 20. The support deck 20 may be a discrete structure or integral with the tester 15. A load board 25 is mounted on the support deck 20. A probe head 30 is mounted on a mounting ring 31 of the load board 25. The load board 25 is typically a printed circuit board and may be single layer or multi-layer and composed of polymeric materials, such as epoxy resins, or well-known ceramic materials. The probe head 30 includes plural conductive leads or needles (not visible in FIG. 1, but shown in subsequent figures). The probe system 10 is typically used with a prober 35, which is designed to hold a semiconductor wafer 37. The prober 35 is operable to precisely move the wafer 37 along three axes. The support deck 20 of the tester 15 is rotated about the axis 32 until the probe head 30 is brought into proximity with the wafer 37. The prober 35 then precisely moves the wafer 37 into contact with the needles of the probe head 30, and the tester 15 runs one or more diagnostic scripts. As described in more detail below, the load board 25 includes plural conductive pathways and electronic components (not visible in FIG. 1). In this way, the tester 15 may send electric signals to the probe head 30 and ultimately the wafer 37 and vice versa. The tester 15 may be a computer system that includes appropriate circuitry, software, and a user interface of one sort or another. A variety of instruments may be used as the tester 15. An application specific tester 15 may be used. Optionally, a commercially-available unit, such as an Agilent 93000 SOC Series may be used. An example of commerically-available prober 35 is a Tokyo Electron model P-12XL.

In the conventional system depicted in FIG. 1, a known good or “golden” wafer 37 is used to verify the operation of the load board 25. This technique not only requires the prober 35, but also the wafer 37, and as such, can result in damage to the wafer 37. However, in this illustrative embodiment depicted in FIG. 2, the tester 15 is provided with hardware and software to enable the tester 15 to perform diagnostics on the load board 25 itself without the need for the prober 35 or the wafer 37. This hardware includes a fixture 50 (shown exploded) that may be mounted to the mounting ring 31 of the load board 25. In this illustrative embodiment, the fixture 50 is shown exploded and includes a shorting substrate 55 mounted to a guide plate 57. The guide plate 57 is coupled to an upper die plate 60. A lower die plate 62 is coupled to the upper die plate 60. As described in more detail below, the shorting substrate 55 is a circuit board that is designed to mimic some of the characteristics of a circuit board that would ordinarily be probed with the system 10 but more importantly to provide specified electrical pathways from the tester 15 to various components internal to the load board 25 that are not visible in FIG. 1, but which are critical to the functionality of the load board 25 and, in-turn, the probe system 10. As described in more detail below, these components may include relays, operational amplifiers, or virtually any other type of logic device utilized in conjunction with the load board 25. The fixture 50 is designed to mount on the mounting ring 31 and used to position the shorting substrate 55 in a desired position relative to the load board 25.

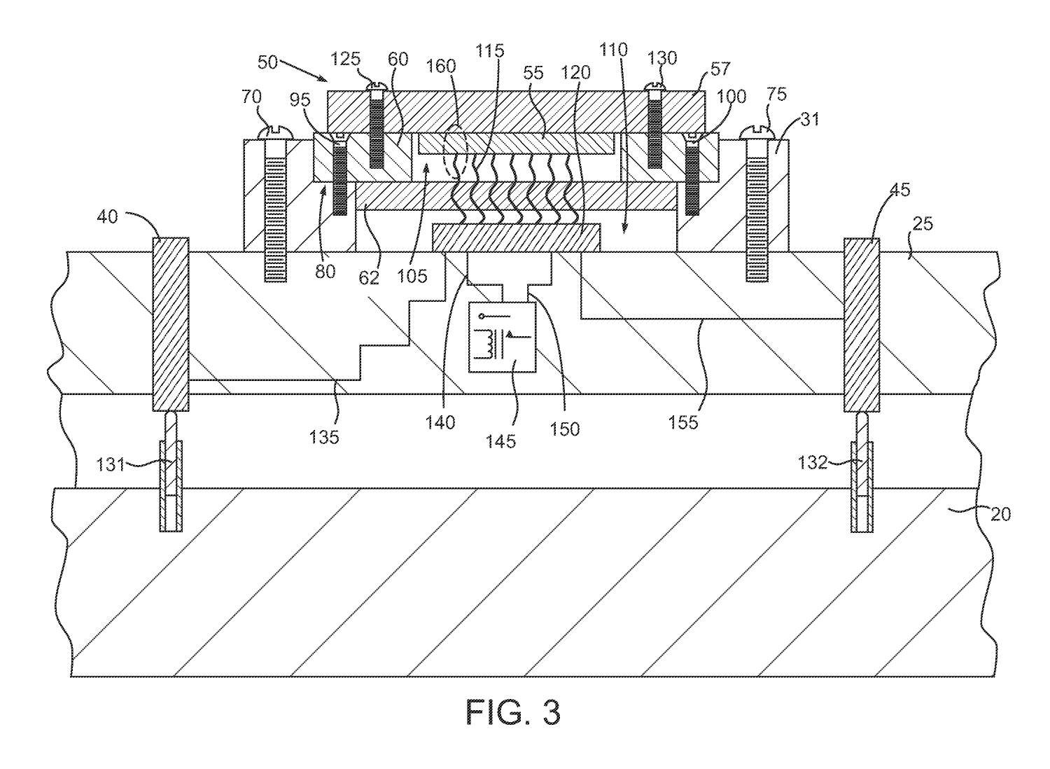

Additional details of the load board 25, the mounting ring 31, the fixture 50 and the shorting substrate 55 thereof may be understood by referring now to FIG. 3, which is a sectional view of the fixture 50 and mounting ring 31 and a small portion of the load board 25 and the support deck 20 to either side of the mounting ring 31 all shown in FIG. 2. The mounting ring 31 may be connected to the load board 25 by way of screws 70 and 75 and perhaps others that are not illustrated. The mounting ring 31 may be constructed of well-known corrosion resistant materials, such as stainless steel, aluminum, plastics or similar materials. Here, the shorting substrate 55 is mounted to the guide plate 57 and the guide plate 57 is, in-turn, mounted to the upper die plate 60. It may be possible to mount the shorting substrate 55 to the mounting ring 31 by screws or other fasteners or fastening techniques without the guide plate 57, thus the term “fixture” need not include the guide plate 57. The fixture 50 may come in a variety of configurations. In this illustrative embodiment, the fixture 50 may include the upper die plate 60, which seats on an upwardly facing shoulder 80 of the mounting ring 31. The upper die plate 60 may be connected to the mounting ring 31 by way of screws 95 and 100 and perhaps others that are not illustrated. Optionally, other types of fastening methods such as solder or other types of adhesives may be used in lieu of or in addition to the screws 95 and 100. The upper die plate 60 includes an internal bore 105 to accommodate the shorting substrate 55. The upper die plate 60 is connected at a lower surface to the lower die plate 62. The lower die plate 62 is positioned within an internal bore 110 of the mounting ring 31. The upper and lower die plates 60 and 62 may be secured by adhesives, solders or other fastening techniques. The lower die plate 62 includes plural probe needles that are collectively labeled 115. The needles 115 project downwardly through the lower die plate 62 and establish electrical contact with a circuit board 120 that is soldered or otherwise mounted to the load board 25. The circuit board 120 may be a multi-level organic or multi-level ceramic circuit board as desired. The needles 115 project upwardly into the internal bore 105 of the upper die plate 60 and establish electrical contact with various portions of the shorting substrate 55 in a manner to be described in more detail below. When seated on the upper die plate 60, the guide plate 57 may be secured thereto by way of the screws 125 and 130 and others that are not visible or by way of or in addition to other fastening techniques such as adhesives, etc.

The POGO pads 40 and 45 are shown in electrical contact with respective POGO pins 131 and 132 of the support deck 20. There may be scores or hundreds of such POGO pins 131 and 132. Traces and other conductors of the support deck 20 that connect to the POGO pins 131 and 132 are not depicted for simplicity of illustration. While POGO pads 40 and 45 and POGO pins 131 and 132 are depicted, other structures for establishing selective electrical contact could be used. As noted above, the load board 25 includes various electrical pathways to provide electrical communication between the POGO pads 35 and 40 and various electrical components of the load board 25. In this illustrative embodiment, an exemplary electrical pathway is schematically represented and consists of an electrical sub-pathway 135 from the POGO pad 40 to the circuit board 120, an electrical sub-pathway 140 from the circuit board 120 to an electronic component 145 of the load board 25, an electrical sub-pathway 150 from the component 145 to the circuit board 120 and an electrical sub-pathway 155 from the circuit board 120 to the POGO pad 45. These electrical sub-pathways 135, 140, 150 and 155 may be fabricated in a large variety of ways, such as, by way of multi-level metallization interconnected by vias or other types of electrical conductor structures, surface traces or other methods.

The component 145 of the load board 25 may be a relay as depicted or virtually any other type of electrical component of a load board that may benefit from diagnostic testing. An exemplary signal pathway might include, for example, a signal delivered from the POGO pin 131 to the POGO pad 40 through the sub-pathway 135, into the circuit board 20, up through one of the probe needles 115 into the shorting substrate 55, back down to the circuit board 120 by way of one of the needles 115, then into the component 145 by way of the sub-pathway 140, then back to the circuit board 120 via the sub-pathway 150, up to the shorting substrate 55 again via one or more of the needles 115 and then ultimately back to the circuit board 120 and to the POGO pad 45 by way of the sub-pathway 155 where it is received by the POGO pin 132. Note that this represents an electrical pathway to just one component 145. However the skilled artisan will appreciate that the load board 25 may include large numbers of components that may be tested in this way but perhaps using alternative electrical pathways through the load board 25. In any event, the integrity and performance of the component 145 may be readily tested using the shorting substrate 55.

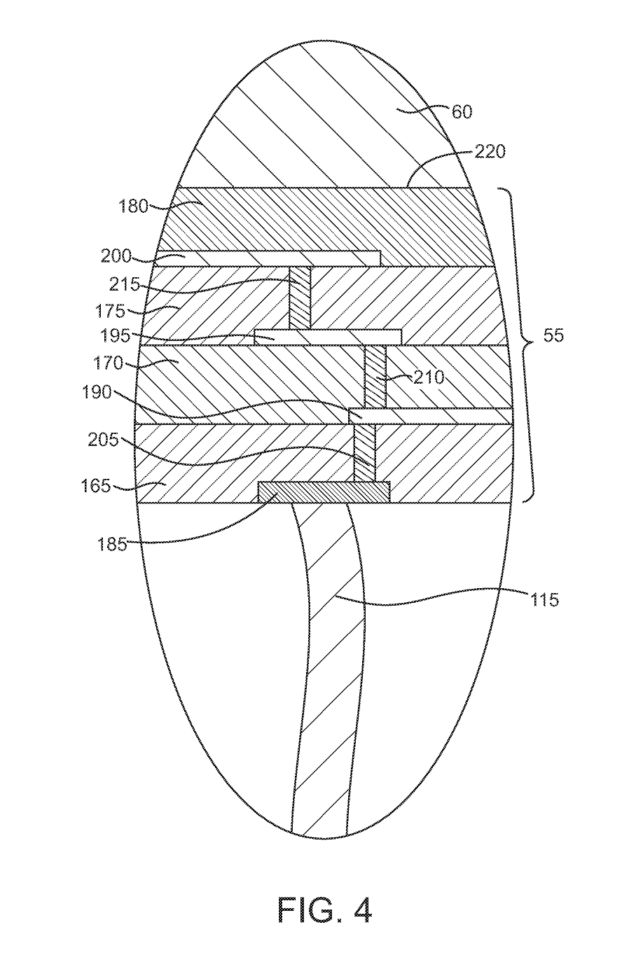

Note the location of the dashed oval 160 in FIG. 3. The portion of FIG. 3 circumscribed by the dashed oval 160 will be shown at greater magnification in FIG. 4 and used to describe additional features of the shorting substrate 55. With that backdrop, attention is now turned to FIG. 4. The shorting substrate 55 may be a monolithic or multi-layered structure. Well-known polymeric materials, such as epoxy resins with or without glass or other filler may be used as well as ceramic materials. If multi-layered, a buildup design or other configuration may be used. In this illustrative embodiment, the shorting substrate 55 may consist of four insulating layers, 165, 170, 175 and 180 that include respective metallization layers 185, 190, 195 and 200 interconnected vertically by way of one of more conductive vias 205, 210 and 215. The insulating layers 165, 170, 175 and 180 may be composed of the aforementioned insulating materials. The metallization layers 185, 190, 195 and 200 and the conductive vias 205, 210 and 215 may consist of various conductor materials, such as copper, silver, nickel, platinum, gold, aluminum, palladium, alloys or laminates of these or the like, and be fabricated using well-known techniques, such as plating, chemical vapor deposition, sputtering, combinations of these or other techniques. It should be understood that while FIG. 4 depicts a multi-level shorting substrate 55, one or more layers may be used as desired. The metallization layer 185 may consist of, or otherwise include, a C4 pad that the needle 115 establishes ohmic contact with as shown. The shorting substrate 55 may be connected to the guide plate 60 at interfacial 220 by adhesives, solder or other fastening techniques. The needle 115 is advantageously provided with a somewhat serpentine configuration to provide a compliant, as opposed to a strictly rigid, contact with the C4 pad 185.

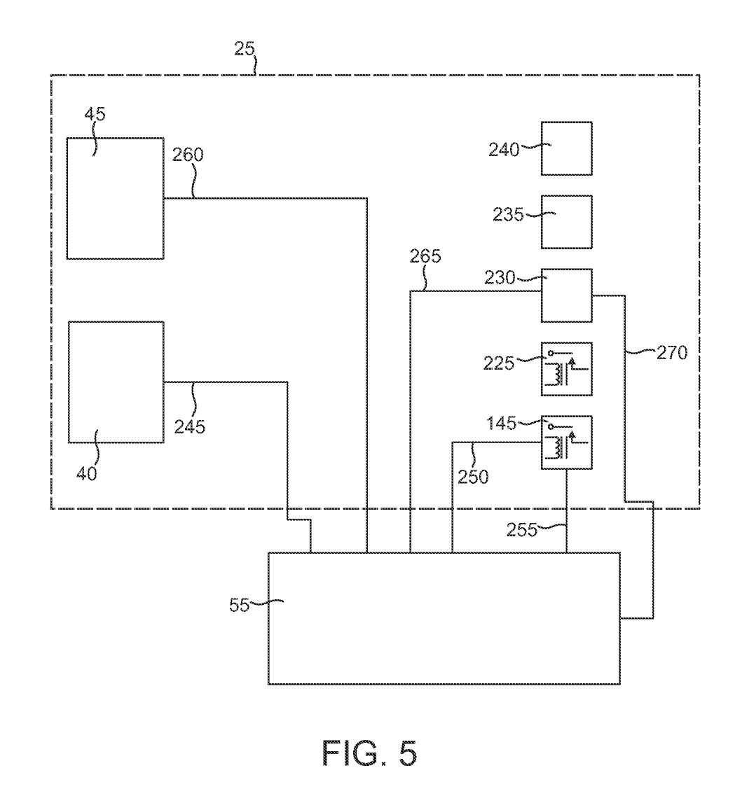

Amore generalized schematic view of the load board 25 and the shorting substrate 55 is depicted in FIG. 5. Here, the load board 25 includes the component 145 as well as additional components 225, 230, 235 and 240. However, as just noted, the load board 25 may include scores or hundreds of such components. The POGO pads 40 and 45 depicted in FIGS. 2 and 3 are represented schematically in FIG. 5. The electrical pathway 245 between the POGO pad 40 and the shorting substrate 55 may include the aforementioned electrical sub-pathway 135, the circuit board 120 and one or more of the probe needles 115 as shown in FIG. 3. The electrical connection or pathway 250 between the shorting substrate 55 and the component 145 of the load board 25 may include one or more of the probe needles 115, the circuit board 120, and the sub-pathway 140 depicted in FIG. 3. Similarly, the electrical pathway 255 from the component 145 to the shorting substrate 55 may include the aforementioned electrical sub-pathway 150 and one or more of the probe needles 115 depicted in FIG. 3. Finally, the electrical pathway 260 between the shorting substrate 55 and the POGO pad 45 may include one or more of the needles 115 and the circuit board 120 and the sub-pathway 155 depicted in FIG. 3. Another pair of I/O electrical pathways 265 and 270 between the shorting substrate 55 and, for example, the component 230 are illustrated. These electrical pathways 265 and 270 may follow the same general structure as the electrical pathways 250 and 255 just described. The same may hold true for any of the components 145, 225, 230, 235 and 240 of the load board 25. In this way, the integrity and performance of any of the components 145, 225, 230, 235 and 240 of the load board 25 may be readily accessed using the shorting substrate 55.

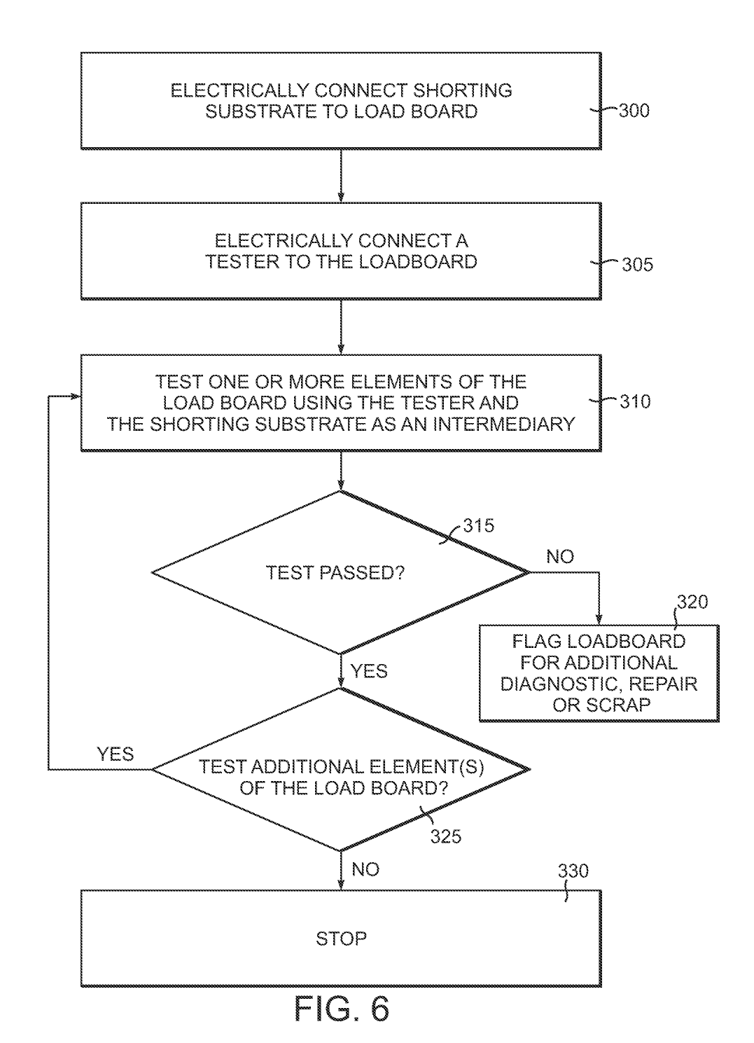

An exemplary testing method utilizing a shorting substrate may be understood by referring now to FIGS. 2, 3, 4 and to FIG. 6, which is a flow chart. Here, at step 300, a shorting substrate is electrically connected to a load board. Referring again to FIG. 3, for example, this step 300 may entail connecting the fixture 50 to the mounting ring 31 so that the shorting substrate 55 connects electrically to the circuit board 120 via the probe needles 115. Next, at step 305, the tester 15 shown in FIG. 1, may be electrically connected to the load board 25. This may entail establishing electrical contact with, for example the POGO pins 131 and 132 and the POGO pads 40 and 45 shown in FIG. 3. Next at step 310, one or more elements of the load board 25 are tested using the tester and the shorting substrate as an intermediary. This will entail using the electrical pathways involving the shorting substrate 55 depicted in FIGS. 3, 4 and 5 and running various software scripts using the tester 15 depicted in FIG. 2 to determine the integrity and performance of various of the internal components of the load board. These diagnostics may include determining electrical continuity, speed performance or other characteristics of the load board components. At step 315, a determination is made as to whether the test on the components passed. If the test failed, then at step 320, the load board may be flagged for additional diagnostic, repair or scrap. If the test at 315 passed, then at step 325 additional testing of other elements of the load board may be performed by repeating step 310. If the testing of additional elements of the load board are not desired at this point then the process may be stopped at step 330.

Any of the exemplary embodiments disclosed herein may be embodied in instructions disposed in a computer readable medium, such as, for example, semiconductor, magnetic disk, optical disk or other storage medium or as a computer data signal. The instructions or software may be capable of synthesizing and/or simulating the circuit structures disclosed herein. In an exemplary embodiment, an electronic design automation program, such as Cadence APD, Encore or the like, may be used to synthesize the disclosed circuit structures. The resulting code may be used to fabricate the disclosed circuit structures.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of testing a load board of a probe testing system, comprising:
electrically engaging a shorting substrate with conductor structures of the load board, the shorting substrate being operable to establish one or more electrical pathways between the tester and at least one electronic component of the load board; and
performing an electrical test on the at least one electronic component using the one or more electrical pathways.

2. The method of claim 1, comprising coupling the shorting substrate to a guide plate and coupling the guide plate to the load board.

3. The method of claim 1, comprising electrically engaging the shorting substrate with the conductor structures of the load board using plural probe needles, the shorting substrate comprising plural conductor structures to engage some or all of the needles.

4. The method of claim 1, wherein the at least one electronic component comprises a relay.

5. The method of claim 1, wherein the shorting substrate comprises a multi-layer circuit board.

6. A method of manufacturing, comprising
fabricating a shorting substrate; and
fabricating plural conductor structures on the shorting substrate, the plural conductor structures being operable to establish ohmic contact with conductor structures of a load board of a probe testing system that includes a tester, the shorting substrate being operable to establish one or more electrical pathways between the tester and at least one electronic component of the load board.

7. The method of claim 6, wherein the conductor structures of the shorting substrate comprise C4 pads.

8. The method of claim 6, wherein the shorting substrate is fabricated as a multi-layer organic circuit board.

9. The method of claim 6, wherein the shorting substrate is fabricated as a multi-layer ceramic circuit board.

10. The method of claim 6, comprising coupling the shorting substrate to a guide plate operable to couple to load board.

11. An apparatus, comprising:
a fixture engagable with a load board of a probe testing system, the probe testing system having a tester, the load board having at least one electronic component; and
wherein the fixture includes a shorting substrate operable to establish one or more electrical pathways between the tester and the least one electronic component.

12. The apparatus of claim 11, wherein the fixture comprises a guide plate coupled to the shorting substrate and operable to be coupled to the load board.

13. The apparatus of claim 11, wherein the load board comprises plural conductor structures, the fixture comprising plural probe needles coupled to the shorting substrate and being operable to electrically contact the conductor structures.

14. The apparatus of claim 11, wherein the at least one component comprises a relay.

15. The apparatus of claim 11, wherein the shorting substrate comprises a multi-layer circuit board.

16. An apparatus, comprising:
a load board having at least one electronic component and being operable to transmit electrical signals to and from a tester; and
a shorting substrate coupled to the load board and being operable to establish one or more electrical pathways between the tester and the least one electronic component.

17. The apparatus of claim 16, comprising a guide plate coupled to the shorting substrate and to load board.

18. The apparatus of claim 16, wherein the load board comprises plural conductor structures, the shorting substrate comprising plural probe needles being operable to electrically contact the conductor structures.

19. The apparatus of claim 16, wherein the at least one component comprises a relay.

20. The apparatus of claim 16, wherein the shorting substrate comprises a multi-layer circuit board.
